(19) United States
(12) Patent Application Publication
(10) Pub. No.: US 2008/0233708 A1
(43) Pub. Date: Sep. 25, 2008

(54) METHOD FOR MANUFACTURING SEMICONDUCTOR DEVICE

(75) Inventor: Hirokazu Hisamatsu, Chino (JP)

Correspondence Address: HARNESS, DICKEY & PIERCE, P.L.C., P.O. BOX 828, BLOOMFIELD HILLS, MI, 48303, US

(73) Assignee: Seiko Epson Corporation, Tokyo (JP)

(21) Appl. No.: 12/051,472

(22) Filed: Mar. 19, 2008

(30) Foreign Application Priority Data
Mar. 20, 2007 (JP) 2007-073258

(51) Int. Cl. H01L 21/322

(52) U.S. Cl. 438/410; 257/E21.32; 257/E21.218

(57) ABSTRACT

A method for manufacturing a semiconductor device includes: forming a first semiconductor layer and a second semiconductor layer sequentially on a semiconductor substrate; forming a first groove penetrating the first semiconductor layer and the second semiconductor layer by partially etching the first semiconductor layer and the second semiconductor layer; forming a support covering the second semiconductor layer from inside of the first groove to a surface of the second semiconductor layer so as to support the second semiconductor layer; etching a sidewall formed in the first groove of the support so as to render the sidewall thin; forming a second groove exposing the first semiconductor layer by sequentially etching a part of the second semiconductor layer and a part of the first semiconductor layer; forming a cavity between the semiconductor substrate and the second semiconductor layer by etching the first semiconductor layer through the second groove under an etching condition in which the first semiconductor layer is more easily etched than the second semiconductor layer; and forming a buried oxide film by thermally oxidizing an upper surface of the semiconductor substrate and a lower surface of the second semiconductor layer that are facing inside of the cavity.

The entire disclosure of Japanese Patent Application No. 2007-073258, filed Mar. 20, 2007 is expressly incorporated by reference herein.

### BACKGROUND

1. Technical Field

The present invention relates to a method for manufacturing a semiconductor device, and particularly relates to a technique to form a silicon-on-insulator (SOI) structure on a semiconductor substrate.

2. Related Art

To enhance performance of a semiconductor device, attempts to form a transistor on a thin film silicon layer (hereinafter, also referred to as an SOI layer) formed on an insulating film are being made with an aim of manufacturing a semiconductor integrated circuit having a circuit element isolated by a dielectric material and having a small stray capacitance. Further, examples of a technique to form the SOI structure on a part of a bulk-Si substrate as required are disclosed in JP-A-2005-354024 and Separation by Bonding Si islands (SBSI) for LSI Applications. (T, Sakai et al.), Second International SiGe Technology and Device Meeting, Meeting Abstract, pp. 230-231, May (2004).

The method disclosed in these examples is called the SBSI method in which an SOI structure is partially formed on a bulk-Si substrate. In the SBSI method, a Si layer and a SiGe layer are formed on a Si substrate, and only the SiGe layer is selectively removed by using difference of etching rate between Si and SiGe so as to form a cavity between the Si substrate and the Si layer. Next, an upper surface of the Si substrate and a lower surface of the Si layer facing inside of the cavity are thermally oxidized so that a SiO₂ film (hereinafter, also referred to as a BOX layer) is formed between the Si substrate and the Si layer. Then, SiO₂ or the like is deposited on the Si substrate by CVD, and planarized by CMP, and further, etched by a diluted hydrofluoric acid (HF) solution or the like so as to expose a surface of the Si layer (i.e. SOI layer) on the BOX layer.

According to the method as above, a manufacturing cost that is a major issue for an SOI device can be reduced while an SOI transistor and a bulk transistor are allowed to be mounted in combination. As a result, a chip area can be reduced while advantages of both the SOI transistor and the bulk transistor are maintained.

In the SBSI method described above, in thermal oxidation to form the BOX layer, the upper surface of the Si substrate and the lower surface of the Si layer facing inside of the cavity are thermally oxidized, growing a SiO₂ film from the Si substrate while growing a SiO₂ film from the Si layer. Then, these SiO₂ films are attached each other at about a center in a height direction inside of the cavity, forming the BOX layer.

However, according to the SBSI method in related art, there have been a case where the Si layer to be the SOI layer and a support for supporting the Si layer are convexly warped due to a stress generated therebetween, resulting in forming a gap in a center portion of the BOX layer after the thermal oxidation. If the gap is formed in the center of the BOX layer, there is a risk in which the SOI layer is detached from the Si substrate by accompanying with a part of the BOX layer in a CMP step later.

Further, even if the SOI layer is not detached, the SOI layer receives a stress, and the stress causes variation of electrical characteristics (e.g. Iₒₙ) of an SOI device on a surface of a wafer. Further, there may be a case where poly-Si for a gate electrode gets into the gap and is deposited therein. This may remarkably increase variation of electrical characteristics (e.g. Vₜₕ) of the SOI device.

### SUMMARY

An advantage of the invention is to provide a method for manufacturing a semiconductor device having a yield improved by reducing a stress generated on a second semiconductor layer (i.e. SOI layer), and further, to provide a method for manufacturing a semiconductor device with high reliability.

A method for manufacturing a semiconductor device according to an aspect of the invention includes forming a first semiconductor layer and a second semiconductor layer sequentially on a semiconductor substrate, forming a first groove penetrating the first semiconductor layer and the second semiconductor layer by partially etching the first semiconductor layer and the second semiconductor layer, forming a support covering the second semiconductor layer from inside of the first groove to a surface of the second semiconductor layer so as to support the second semiconductor layer, etching a sidewall formed in the first groove of the support so as to render the sidewall thin, forming a second groove exposing the first semiconductor layer by sequentially etching a part of the second semiconductor layer and a part of the first semiconductor layer, forming a cavity between the semiconductor substrate and the second semiconductor layer by etching the first semiconductor layer through the second groove under an etching condition in which the first semiconductor layer is more easily etched than the second semiconductor layer, and forming a buried oxide film by thermally oxidizing an upper surface of the semiconductor substrate and a lower surface of the second semiconductor layer that are facing inside of the cavity.

In this case, the etching the sidewall to render the sidewall thin may include forming a slit by partially etching the sidewall.

Here, when the buried oxide film is formed, one thermally oxidized film growing from a semiconductor substrate side and the other thermally oxidized film growing from a second semiconductor layer side are attached each other at about the center of the cavity. Then, after the oxidized films are attached each other, the oxidized films grow so as to broaden upward and downward from an interface where the oxidized films are attached each other as a center (that is, as they expand). At this time, the second semiconductor layer supported by the support receives force to push upward from the oxidized film located immediately below the second semiconductor layer.

According to the method for manufacturing a semiconductor device as above, strength of the sidewall of the support can be reduced to an extent in which ability to support the second semiconductor layer is not affected. Then, when the buried oxide film is formed, by receiving a softening effect of the support itself due to a treatment temperature and force caused by the volume expansion of the oxidized film, a thin film portion of the sidewall (e.g. a portion in which the slit is formed) can be stretched in the upper direction. Therefore, when the buried oxide film is formed, the second semiconductor layer is moved upward (that is, to be lifted), thereby releasing the force to push upward applied to the second semiconductor layer from the buried oxide film.

According to the above, while the stress on the second semiconductor layer is reduced, the second semiconductor layer is prevented from warping, thereby maintaining favorable adherence between the oxidized films (which are forming the buried oxide film). Therefore, the oxidized films are prevented from being detached at the interface where the oxidized films are attached each other in a later step. Further, the second semiconductor layer formed on the oxidized film is prevented from being detached from the semiconductor substrate by accompanying with the oxidized film.

As a result, the stress on the second semiconductor layer (i.e. SOI layer) is reduced, improving a yield of the semiconductor device. In addition, the second semiconductor layer is prevented from being detached from the semiconductor substrate, providing high reliability as a semiconductor device.

Further, since the stress on the second semiconductor layer is reduced, it contributes to reduce variation of electrical characteristics of a device formed on the second semiconductor layer (i.e. an SOI device).

In this case, the method for manufacturing a semiconductor device may further include forming side surfaces of the second semiconductor and the first semiconductor that face the first groove of the second semiconductor layer and the first semiconductor layer to be in a continuous tapered shape in a sectional view so as to spread gradually wider from the second semiconductor layer to the first semiconductor layer before the support is formed. According to the above, the sidewall of the support is formed on a slant along the tapered side surfaces of the second semiconductor layer and the first semiconductor layer, thereby rendering a side surface of the sidewall (that is, the surface to be etched) to face an upside of the semiconductor substrate. Accordingly, forming the slit or the like is facilitated compared with a case where the sidewall is formed perpendicular to the surface of the semiconductor substrate.

In this case, the method for manufacturing a semiconductor device may further include filling the slit with an expansion member whose volume expands by thermal oxidation before the buried oxide film is formed. According to the above, when the buried oxide film is formed, expansibility of the expansion member can assist the stretch of the sidewall of the support, thereby further reducing the stress on the second semiconductor layer. Further, since the slit is filled, at least the portion where the silt is formed in the sidewall is enforced in strength. As a result, strength of the sidewall that is reduced due to forming the slit is compensated, thereby highly maintaining the ability of the support to support the second semiconductor layer.

### BRIEF DESCRIPTION OF THE DRAWINGS

The invention will be described with reference to the accompanying drawings, wherein like numbers reference like elements.

FIGS. 1A and 1B are diagrams showing a method for manufacturing a semiconductor device according to a first embodiment.

FIGS. 2A and 2B are diagrams showing the method for manufacturing a semiconductor device according to the first embodiment.

FIGS. 3A and 3B are diagrams showing the method for manufacturing a semiconductor device according to the first embodiment.

FIGS. 4A and 4B are diagrams showing the method for manufacturing a semiconductor device according to the first embodiment.

FIGS. 5A and 5B are diagrams showing the method for manufacturing a semiconductor device according to the first embodiment.

FIGS. 6A and 6B are diagrams showing the method for manufacturing a semiconductor device according to the first embodiment.

FIGS. 7A through 7D are diagrams showing an example of a method for forming a support 22 and slits 23.

FIGS. 8A through 8C are diagrams showing other examples of the silts 23.

FIGS. 9A and 9B are diagrams showing a method for manufacturing a semiconductor device according to a second embodiment.

FIGS. 10A and 10B are diagrams showing the method for manufacturing a semiconductor device according to the second embodiment.

FIGS. 11A and 11C are diagrams showing the method for manufacturing a semiconductor device according to the second embodiment.

FIGS. 12A and 12B are diagrams showing a method for manufacturing a semiconductor device according to a third embodiment.

FIGS. 13A and 13B are diagrams showing the method for manufacturing a semiconductor device according to the third embodiment.

FIGS. 14A and 14B are diagrams showing the method for manufacturing a semiconductor device according to the third embodiment.

FIGS. 15A and 15B are diagrams showing the method for manufacturing a semiconductor device according to the third embodiment.

### DESCRIPTION OF EXEMPLARY EMBODIMENTS

Hereinafter, embodiments of the invention will be described with reference to the accompanying drawings.

### First Embodiment

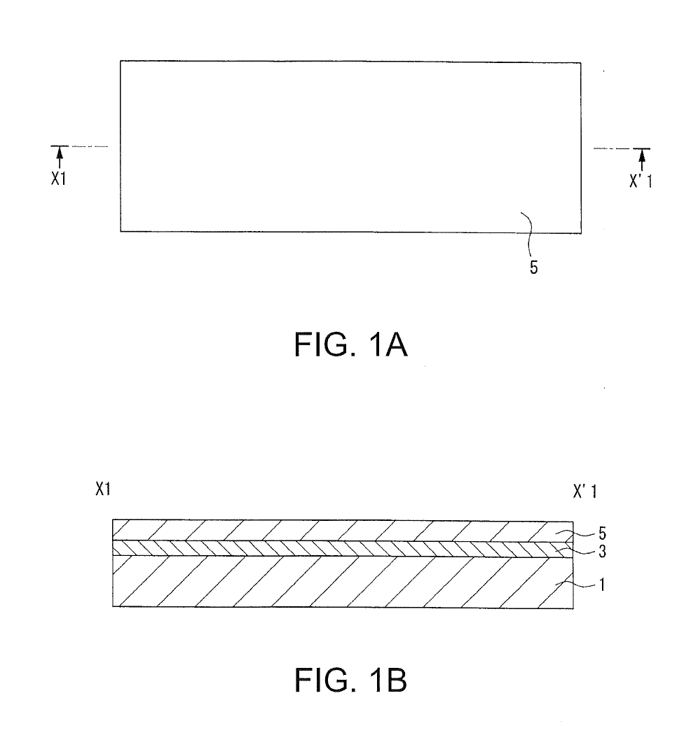

FIGS. 1A through 6B are schematic views showing a method for manufacturing a semiconductor device according to a first embodiment of the invention. In FIGS. 1A through 6B, figures suffixed with the letter “A” are plan views. Figures suffixed with the letter “B” are sectional views respectively taken along the lines X1-X′1 to X6-X′6 of the figures suffixed with the letter “A”.

Referring to FIGS. 1A and 1B, first, a silicon germanium (SiGe) layer 3 and a Si layer 5 that have a single crystal structure are sequentially formed on a Si substrate 1. The SiGe layer 3 and the Si layer 5 are formed in succession by epitaxial growth, for example.

Here, before the SiGe layer 3 is formed, a silicon buffer (Si-buffer) layer having a single crystal structure, which is not shown, may be thinly formed on the Si substrate 1, and then the SiGe layer 3 and the Si layer 5 are sequentially formed thereon. In this case, it is preferable that the Si-buffer layer, the SiGe layer 3, and the Si layer 5 be sequentially formed by epitaxial growth, for example. Film quality of a semiconductor film that is formed by epitaxial growth is largely affected by a crystalline state of a surface where the film is formed (that is, a foundation). Therefore, instead of forming the SiGe layer 3 directly on the Si substrate, the Si-buffer layer having less crystal defects than the surface of the Si substrate 1 is formed to interpose between the Si substrate 1 and the SiGe layer 3, enabling improvement of the film quality of the SiGe layer 3 (e.g. reduction of crystal defects).

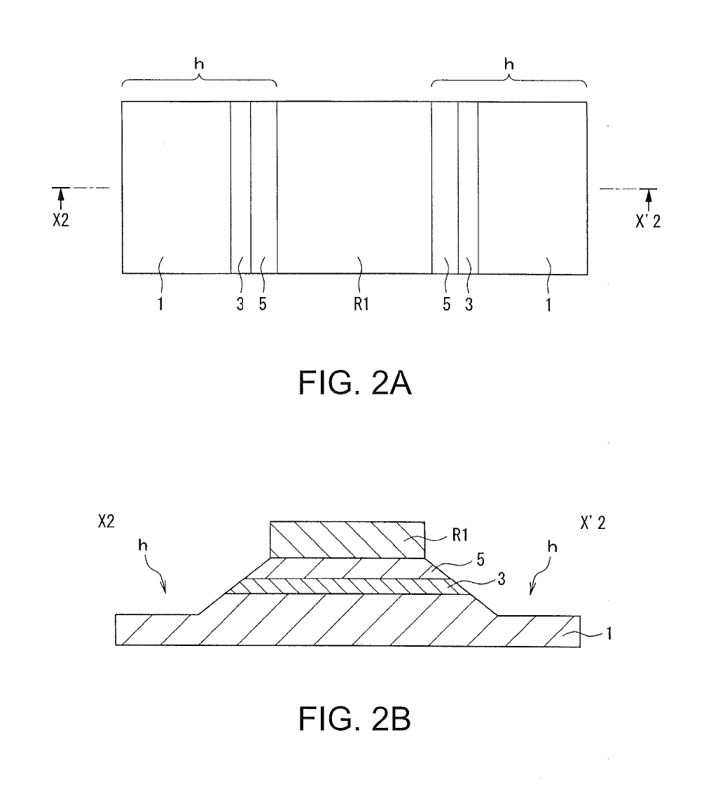

Next, as shown in FIGS. 2A and 2B, a resist pattern R1 in a shape exposing a region to form a support recess h, but covering an element region (that is, a region to form an SOI structure) and a region to form a groove H for removing SiGe later is formed on the Si layer 5. Then, the Si layer 5 and the SiGe layer 3 are dry-etched on a slant by using the resist pattern R1 as a mask so as to form the support recess h. Here, “dry-etched on a slant” means that side surfaces of the layers to be etched are dry-etched so as to spread toward outside from immediately below the resist pattern R1.

That is, a by-product is generated by dry-etching the Si layer 5 and the SiGe layer 3, and adheres to the side surfaces of the Si layer 5 and the SiGe layer 3 in the middle of etching. Then, the by-product adhering to the side surfaces can serve as a mask that delays an etching speed in a direction of the side surfaces (lateral direction). As a result, as shown in FIGS. 2A and 2B, the side surfaces of the Si layer 5 and the SiGe layer 3 are formed in a tapered shape so as to spread wider from the Si layer 5 to the SiGe layer 3. When Si is dry-etched, as an etching condition, for example, dry-etching by plasma under a reduced-pressure atmosphere about 30 to 200 mTorr using a mixed gas of HBr, Cl₂, and O₂, a mixed gas of HBr and O₂, a mixed gas of Cl₂ and O₂, or SF₆ gas can be employed so as to form the side surfaces on a slant. Further, when SiGe is dry-etched, an etching condition that is the same as above can be employed so as to form the side surfaces on a slant. Accordingly, without changing the etching conditions depending on Si and SiGe, the side surfaces are formed to be on a slant with respect to a surface of the Si substrate 1.

In the etching to form the support recess h, the support recess h may be etched until reaching the surface of the Si substrate 1, or the Si substrate 1 may be over etched so as to form a depressed portion as shown in FIG. 2B.

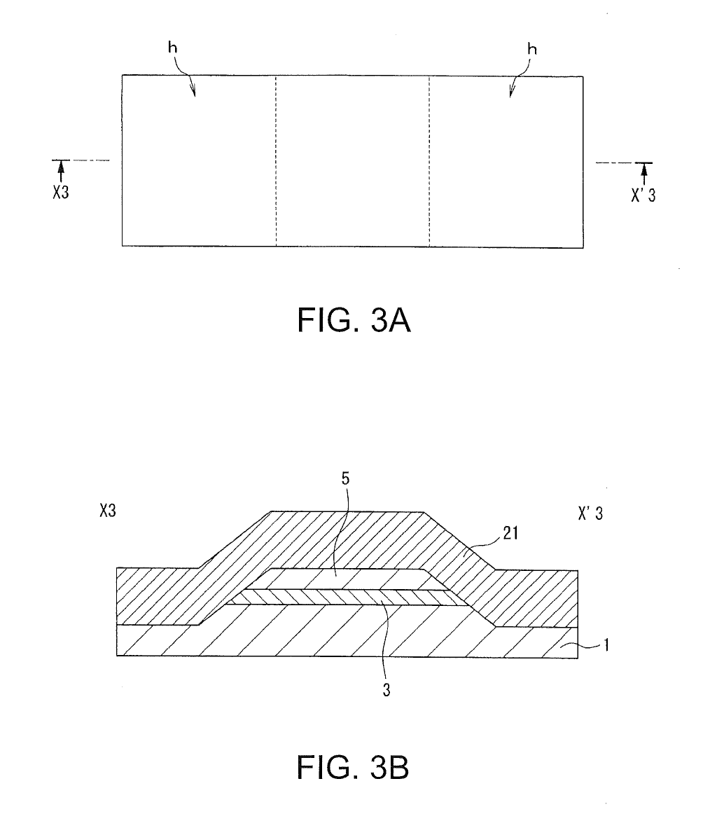

Next, the resist pattern R is removed by ashing, for example. Then, as shown in FIGS. 3A and 3B, a support film 21 is formed on a whole of an upper surface of the Si substrate 1. The support film 21 is, for example, a SiO₂ film, and formed by CVD. The thickness of the support film 21 is about 400 nm, for example.

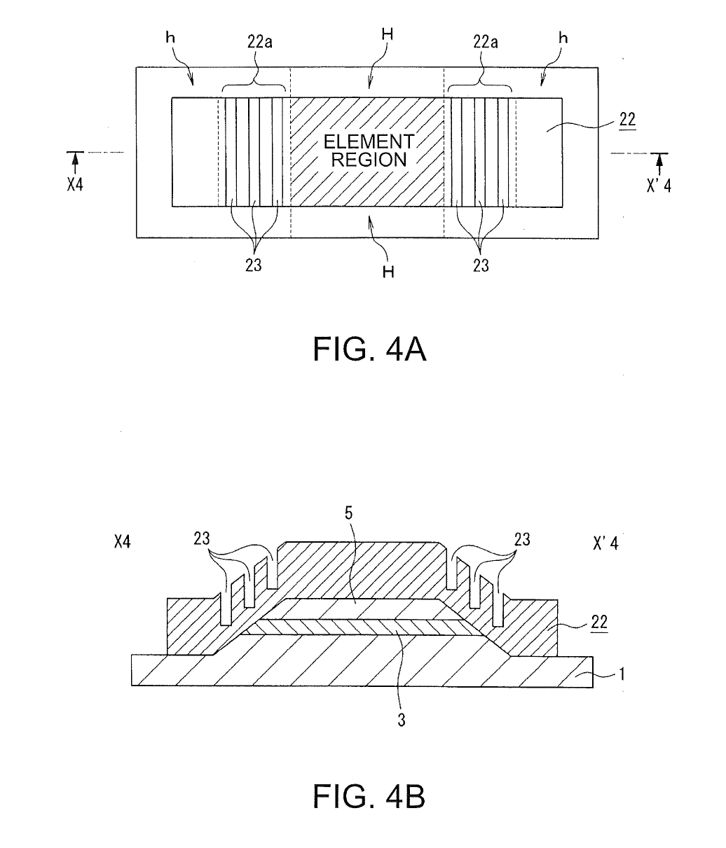

Next, as shown in FIGS. 4A and 4B, a part of the support film 21, a part of the Si layer 5, and a part of the SiGe layer 3 that are in an area overlapping with an element isolation region in a plan view are sequentially etched by photolithography and etching, for example. As a result, a support 22 is formed from the support film 21 while the groove H is formed so as to have the Si substrate 1 as a bottom thereof and expose sides of the Si layer 5 and the SiGe layer 3. Here, the groove H serves as an inlet of an etchant when the SiGe layer 3 is etched later.

Further, before, after, or at the same time as that the support 22 and the groove H are formed, slits 23 are formed in side surfaces of sidewalls 22a of the support 22, which are formed to be on a slant, (that is, portions covering the side surfaces of the SiGe layer 3 and the Si layer 5 that are facing the support recess h) as shown in FIGS. 4A and 4B. Here, the slits 23 in a linear shape are formed from one end to the other end of the support 22 along a short side direction of the support 22. The slits 23 are formed symmetrically across the element region. Further, the slits 23 should have a depth in which ability of the support 22 to support the Si layer 5 is not affected. One example thereof is about 200 nm. The slits 23 as above may be formed by photolithography and etching, for example.

Further, according to this embodiment of the invention, the supporting body 22 and the slits 23 are allowed to be formed concurrently by a single dry-etching.

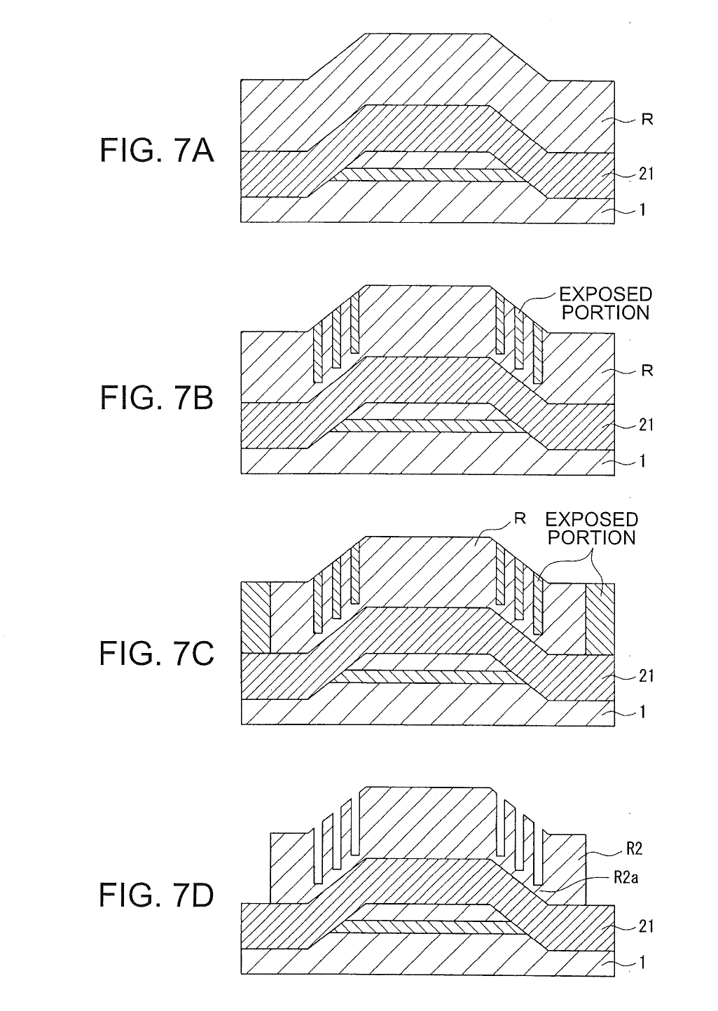

For example, as shown in FIG. 7A, after the support film 21 is formed on the Si substrate 1, a positive photoresist R is applied on the support film 21. Next, a photo mask for slit forming is prepared and arranged in a stepper or the like. Then, first exposure treatment is performed to the photoresist R. Here, in the first exposure treatment, an amount of exposure is kept low so as to expose the photoresist R insufficiently. Therefore, as shown in FIG. 7B, only an upper portion of the photoresist R corresponding to the slits is exposed while a portion thereunder remains unexposed. After the first exposure treatment is completed, the photo mask for the slit forming is removed from the stepper.

Subsequently, a photo mask for support forming is prepared and arranged in the stepper so as to perform second exposure treatment to the photoresist R. Here, in the second exposure treatment, the amount of exposure is set at a sufficient value to completely expose the photoresist R from top to bottom. Accordingly, as shown in FIG. 7C, the photoresist R is exposed to be in a shape of the support.

Thereafter, the photoresist R in which the first and second exposure treatment have been performed is developed so as to remove the exposed portion of the photoresist R. Accordingly, as shown in FIG. 7D, a resist pattern R2 having slits is formed. Then, the support film 21 is dry-etched by using the resist pattern R2 as a mask. At this time, since bottom surfaces R2a of the slits of the resist pattern R2 remain unopened, the slits 23 in the support film 21 are not yet formed at the beginning of the etching. However, as the etching of the support film 21 proceeds, the bottom surfaces R2a of the slits of the resist pattern R2 are etched and then removed so as to open, the slits 23 start being formed in the support film 21 in the middle of the etching.

According to the above, the support 22 and the slits 23 are concurrently formed. Therefore, when the etching is finished, the support 22 having the slits 23 is completed as shown in FIGS. 4A and 4B. After the support 22 is completed, the Si layer 5 and the SiGe layer 3 that are exposed from under the support 22 are sequentially dry-etched so as to form the groove H.

In the etching for forming the groove H, the SiGe layer 3 may be etched halfway to leave a part of the SiGe layer 3 on the Si substrate 1 or the Si substrate 1 may be over etched so as to form a depressed portion.

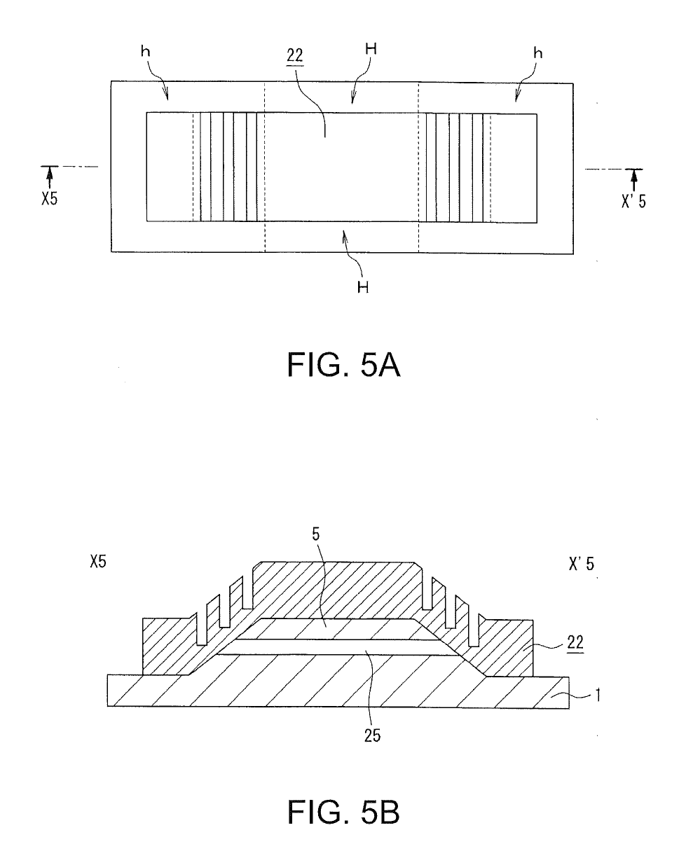

Then, a hydrofluoric-nitric acid solution, for example, is brought into contact with the respective sides of the Si layer 5 and the SiGe layer 3 through the groove H so as to selectively etch and remove the SiGe layer 3. Accordingly, a cavity 25 is formed between the Si layer 5 and the Si substrate 1 as shown in FIGS. 5A and 5B. In wet etching with a hydrofluoric-nitric acid solution, since an etching rate of SiGe is higher than that of Si (that is, etching selectivity with respect to Si is high), only the SiGe layer 3 is removed by etching while the Si substrate 1 and the Si layer 5 remain. In the middle of forming the cavity 25, the upper surface and the side surfaces of the Si layer 5 are supported by the support 22.

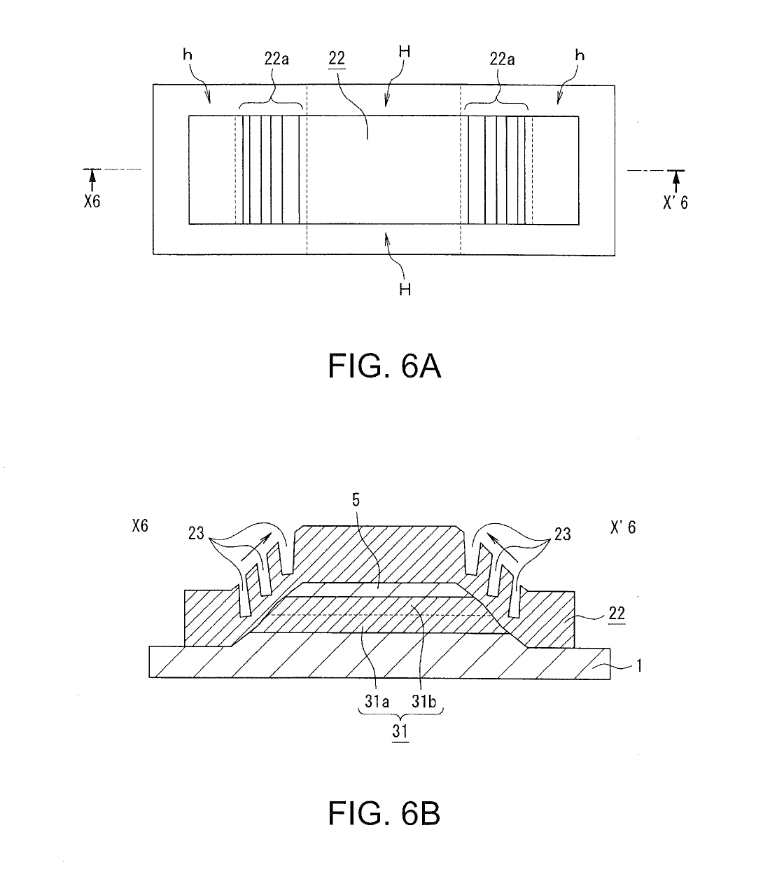

Next, the Si substrate 1 is placed in an oxidizing atmosphere of oxygen (O₂) or the like so as to thermally oxidize the upper surface of the Si substrate 1 and the lower surface of the Si layer 5 that are facing inside of the cavity 25, thereby forming a SiO₂ film (that is, a BOX layer 31) in the cavity 25 as shown in FIGS. 6A and 6B. In forming the BOX layer 31, a SiO₂ film 31a grows upward from the Si substrate 1 while a SiO₂ film 31b grows downward from the Si layer 5. Then, the SiO₂ films 31a and 31b growing from upper and lower directions are attached each other at about the center of the cavity 25.

Here, when a composition of Si is changed from Si to SiO₂ by the thermal oxidation, its volume expands about twice as much. In the forming the BOX layer 31, the SiO₂ films 31a and 31b increase their volumes and grow while filling the cavity 25. Further, after the SiO₂ films 31a and 31b are attached each other at about the center of the cavity 25, a space that can absorb volume expansion of the SiO₂ films 31a and 31b is not left inside of the cavity 25. Therefore, the Si substrate 1 receives force pushing downward from the SiO₂ film 31a located immediately above the Si substrate 1. Furthermore, the Si layer 5 receives force pushing upward from the SiO₂ film 31b located immediately under the Si layer 5.

However, in the first embodiment, by receiving a softening effect of the support 22 itself due to a high temperature at the thermal oxidation and a stress caused by the volume expansion of the SiO₂ films 31a and 31b (that is, force to expand upward and downward from an interface of the SiO₂ films 31a and 31b as a center), a portion of the sidewalls 22a formed with the slits 23 (that is, around the bottom surfaces of the slits 23) is stretched in the upper direction. Therefore, the Si layer 5 can be moved in the upper direction (that is, lifted up) in accordance with the volume expansion of the SiO₂ films 31a and 31b, thereby reducing the force on the Si layer 5 from the SiO₂ film 31a.

As shown in FIGS. 6A and 6B, after the BOX layer 31 is formed, the SOI structure is completed with a same procedure as that of the SBSI method in related art. That is, by CVD or the like, an insulating film, which is not illustrated, is formed on the whole surface of the Si substrate 1 so as to fill the support recess h and the groove H. The insulating film is made of SiO₂, for example. Next, the insulating film and the support 22 thereunder are planarized by CMP, for example, and further wet etched with a dilute hydrofluoric acid (HF) solution.

Accordingly, the insulating film and the support 22 are thoroughly removed from the Si layer 5 (hereinafter, also referred to as the SOI layer 5), thereby completing the SOI structure composed of the BOX layer 31 and the SOI layer 5 in an SOI region on the Si substrate 1. A region other than the SOI region on the Si substrate 1 is filled with the insulating film and the support 22, and serves as an element isolation layer. After the SOI structure is formed on the Si substrate 1, for example, a complete-depletion MOS transistor, a partial-depletion MOS transistor, or the like is formed on the SOI layer 5.

As above, according to the first embodiment of the invention, strength of the sidewalls 22a of the support 22 can be reduced to an extent in which support ability for the SOI layer 5 is not affected. Further, in forming the BOX layer 31, by receiving the softening effect of the support 22 itself due to a treatment temperature and force caused by the volume expansion of the SiO₂ films 31a and 31b, the portion of the sidewalls 22a formed with the slits 23 can be stretched in the upper direction. Therefore, when the BOX layer 31 is formed, the SOI layer 5 is lifted up, thereby releasing the force to push upward applied to the SOI layer 5 from the BOX layer 31.

Accordingly, the stress on the SOI layer 5 is reduced, while the SOI layer 5 is prevented from convexly warping, favorably maintaining adherence of the SiO₂ films 31a and 31b to each other. Therefore, the SiO₂ films 31a and 31b are prevented from being detached from the interface where the SiO₂ films 31a and 31b are attached each other, preventing the SOI layer 5 formed thereon from being detached from the Si substrate 1 by accompanying with the SiO₂ film 31b.

As a result, the stress on the SOI layer 5 is reduced, improving a yield of the semiconductor device. In addition, detachment of the SOI layer 5 from the Si substrate 1 is prevented, providing high reliability as a semiconductor device.

Further, since the stress on the SOI layer 5 is reduced, it contributes to reduce variation of electrical characteristics of a device formed on the SOI layer 5 (i.e. an SOI device).

Furthermore, in the first embodiment of the invention, the side surfaces of the Si layer 5 and the SiGe layer 3 are formed in a tapered shape, enabling the sidewalls 22a of the support 22 to be formed on a slant and enabling the side of the sidewalls 22a to face an upside of the Si substrate 1. Therefore, the slits 23 are easily formed compared with a case where the sidewalls 22a are formed perpendicular to the surface of the Si substrate 1.

Here, in the first embodiment, as shown in FIG. 4A, a case where the slits 23 in a linear shape are formed from one end to the other end of the sidewalls 22a along the short side direction of the support 22 has been described. However, a position to form the slits 23 and the shape of the slits 23 are not limited to this.

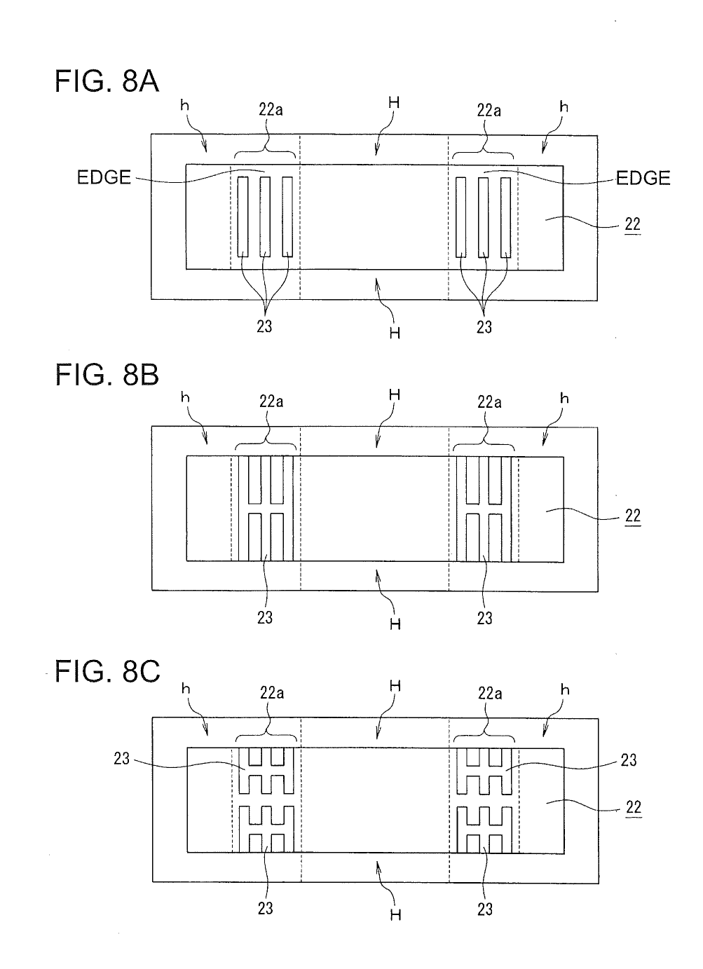

For example, as shown in FIG. 8A, instead of forming the slits 23 in the linear shape about edges of the sidewalls 22a, the slits 23 may be formed only in a position apart from the edges. In this case, the bottom of the slits 23 may reach the Si layer or the SiGe layer. Further, as shown in FIGS. 8B and 8C, one each or a plurality of the slits 23 in a shape in which two Hs rotated by 90 degrees are arranged in tandem or the like in a plan view may be formed equally in right and left across the element region.

Even in such a structure, the strength of the sidewalls 22a is reduced to the extent in which the ability to support the Si layer 5 is not affected. In addition, in the forming the BOX layer 31, by receiving the softening effect of the support 22 itself due to the treatment temperature and the stress caused by the volume expansion of the BOX layer 31, the sidewalls 22a can be stretched in the upper direction. Therefore, the same advantageous effect as the first embodiment can be obtained.

### Second Embodiment

In the first embodiment above, a case where the slits 23 are formed in the sidewalls 22a of the support 22, and while the slits 23 remain as they are, BOX oxidation is performed is described. However, in the second embodiment, instead of letting the slits 23 remain as they are, the BOX oxidation may be performed in a state in which the slits 23 is filled with Si, for example. In the second embodiment, the case as above will be explained.

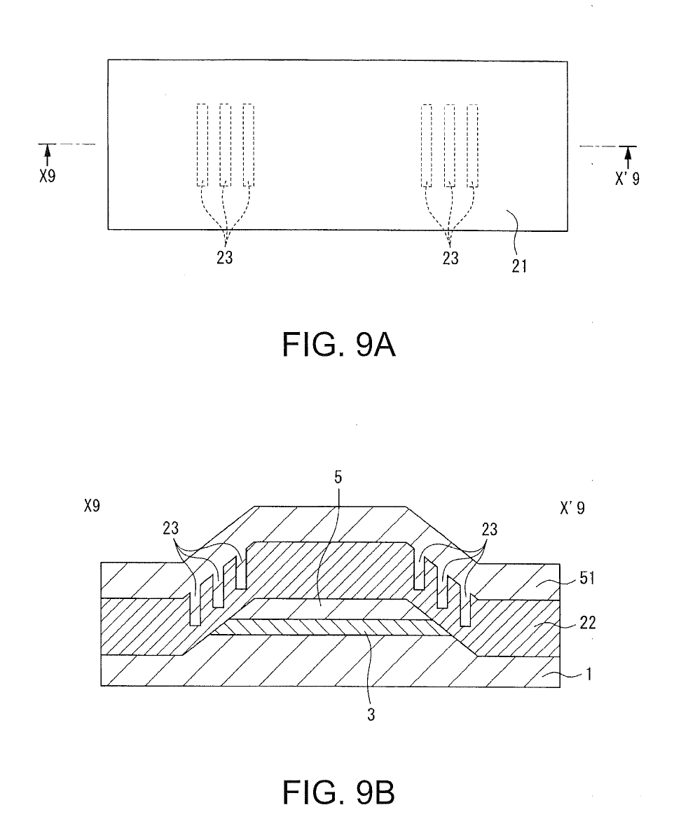

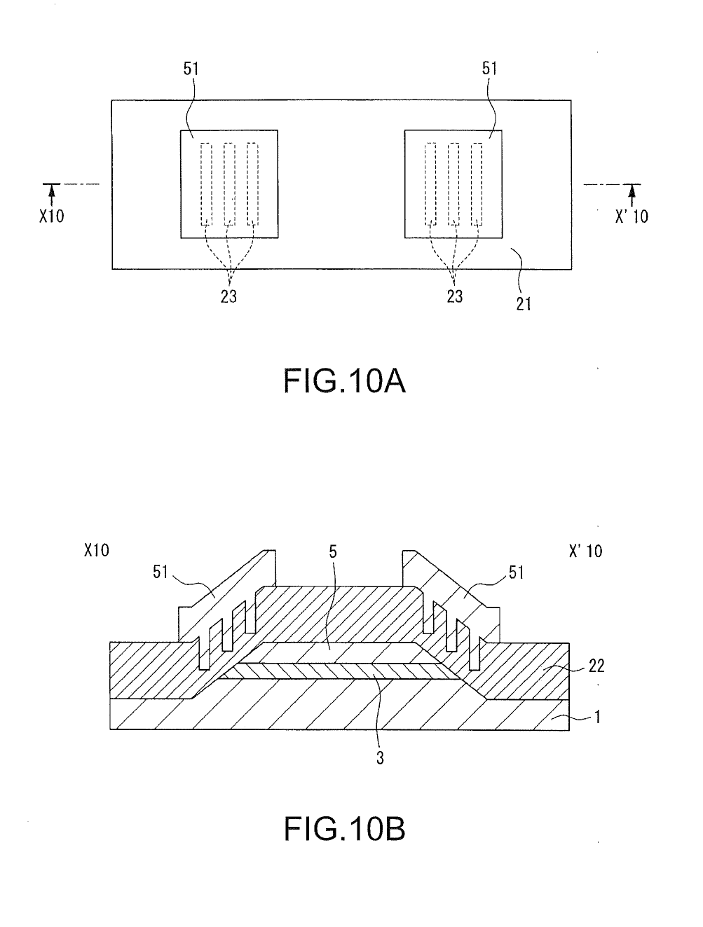

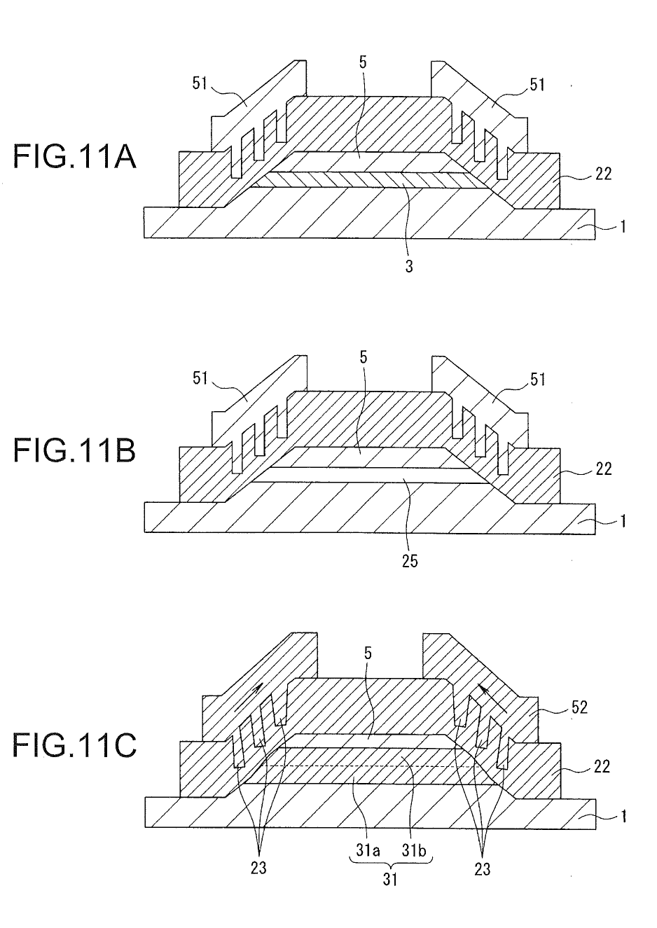

FIGS. 9A through 11C are diagrams showing a method for manufacturing a semiconductor device according to the second embodiment of the invention. FIGS. 9A and 10A are plan views, while FIGS. 9B and 10B are sectional views respectively taken along the lines X9-X′9 and X10-X′10 in FIGS. 9A and 10A. Further, FIGS. 11A through 11C are sectional views taken at the section line X10-X′10 showing manufacturing steps after a step shown in FIG. 10B. In FIGS. 9A through 11C, portions having the same structure and function as those in FIGS. 1A through 8C described in the first embodiment are denoted by the same reference numerals, and descriptions thereof will be omitted.

In the second embodiment, as shown in FIGS. 9A and 9B, after the slits 23 are formed in the support film 21, a Si film 51 is formed on the whole surface of the support film 21 so as to fill the slits 23. The Si film 51 has an amorphous structure or a polycrystalline structure, and formed by CVD, for example.

Next, as shown in FIGS. 10A and 10B, the Si film 51 is patterned by photolithography and etching so as to leave the Si film 51 in the slits 23, while the Si film 51 is removed from the surface of the support film 21 in the element region. Then, the support film 21 is patterned by photolithography and etching so as to form the support 22 as shown in FIG. 11A.

Next, an etchant such as a hydrofluoric-nitric acid solution is brought into contact with the sides of the Si layer 5 and the SiGe layer 3 through the groove H (e.g. refer to FIG. 4A) so as to selectively etch and remove the SiGe layer 3. Accordingly, the cavity 25 is formed between the Si layer 5 and the Si substrate 1 as shown in FIG. 11B. Then, the Si substrate 1 is placed in an oxidizing atmosphere of oxygen (O₂) or the like so as to thermally oxidize the upper surface of the Si substrate 1 and the lower surface of the Si layer 5 that are facing inside of the cavity 25, thereby forming the BOX layer 31 in the cavity 25 as shown in FIG. 11C.

At this time, the Si film 51 filled in the silts 23 is also changed into a SiO₂ film 52 by the thermal oxidation, so that its volume becomes about twice as much. Then, expansive force caused when the Si film 51 becomes the SiO₂ film 52 assists the silts 23 to broaden. In addition, after the BOX layer 31 is formed, the SOI structure is completed with the same procedure as that of the SBSI method in related art.

As the above, according to the second embodiment of the invention, in the forming the BOX layer 31, the expansive force caused when the Si film 51 becomes the SiO₂ film 52 can assist the sidewalls 22a of the support 22 to stretch, thereby facilitating the SOI layer 5 to lift up. Accordingly, the stress on the SOI layer 5 can be further reduced.

In addition, by covering the side surfaces of the sidewalls 22a so as to fill the slits 23, improving the strength of the sidewalls 22a described above. As a result, the strength of the sidewalls 22a that is reduced due to forming the slits 23 is compensated, thereby highly maintaining the ability of the support 22 to support the SOI layer 5.

### Third Embodiment

In the first and second embodiments described above, a case where the side surfaces of the Si layer 5 and the SiGe layer 3 are formed in a tapered shape has been explained. However, the invention is not limited to this, and the side surfaces described above may be perpendicular to the surface of the Si substrate 1.

Further, in the first and second embodiments described above, a case where the sidewalls 22a of the support 22 are partially etched so as to form the slits 23 has been described. However, in the third embodiment, the slits 23 are not formed in the sidewalls 22a, but the sidewalls 22a can be formed to be a thin film so as to obtain stretch as required when the BOX layer 31 is formed. In the third embodiment, the case as above will be explained.

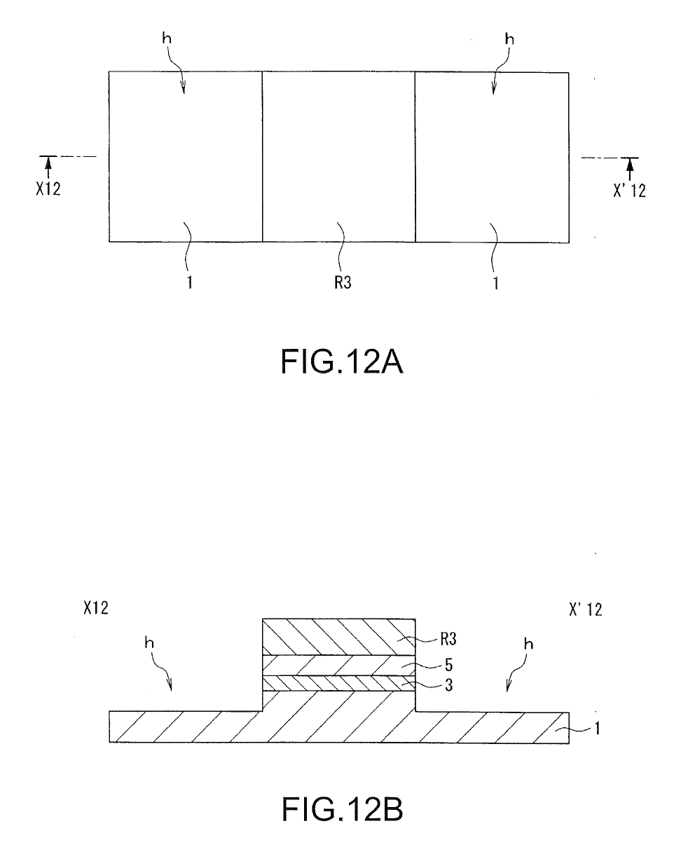

FIGS. 12A through 15B are diagrams showing a method for manufacturing a semiconductor device according to the third embodiment of the invention. In FIGS. 12A through 15B, figures suffixed with the letter “A” are plan views. Figures suffixed with the letter “B” are sectional views respectively taken along the lines X12-X′12 through X15-X′15 of the figures suffixed with the letter “A”. In FIGS. 12A through 15B, portions having the same structure and function as those in FIGS. 1A through 8C described in the first embodiment are denoted by the same reference numerals, and descriptions thereof will be omitted.

As shown in FIGS. 12A and 12B, after the SiGe layer 3 and the Si layer 5 are sequentially formed on the Si substrate 1 by epitaxial growth, a resist pattern R3 is formed on the Si layer 5. Then, the Si layer 5 and the SiGe layer 3 are perpendicularly dry-etched by using the resist pattern R3 as a mask so as to form the support recess h. Here, “perpendicularly dry-etched” means that the side surfaces of the layers to be etched are etched so as to be perpendicular to the surface of the Si substrate 1. In the third embodiment, unlike the first embodiment, the Si layer 5 and the SiGe layer 3 are anisotropically dry-etched in a condition in which a by-product is not generated in the middle of etching (or even if a by-product is generated, it does not adhere to the side surfaces of the Si layer 5 and the SiGe layer 3, or even if it adheres, it is shortly detached.)

When Si is dry-etched, as an etching condition, for example, dry-etching by plasma under a reduced-pressure atmosphere about 5 to 100 mTorr using a mixed gas of HBr, Cl₂, and O₂, a mixed gas of HBr and O₂, a mixed gas of Cl₂ and O₂, a mixed gas of CF₄ and O₂, or SF₆ gas can be employed so as to form the side surfaces perpendicular to the surface of the Si substrate 1. Further, when SiGe is dry-etched, an etching condition that is the same as above can be employed so that the side surfaces are formed to be perpendicular to the surface of the Si substrate 1. According to the above, as shown in FIGS. 12A and 12B, the support recess h is formed in the Si substrate 1. Without changing the etching conditions depending on Si and SiGe, the side surfaces are thus formed to be perpendicular to the surface of the Si substrate 1.

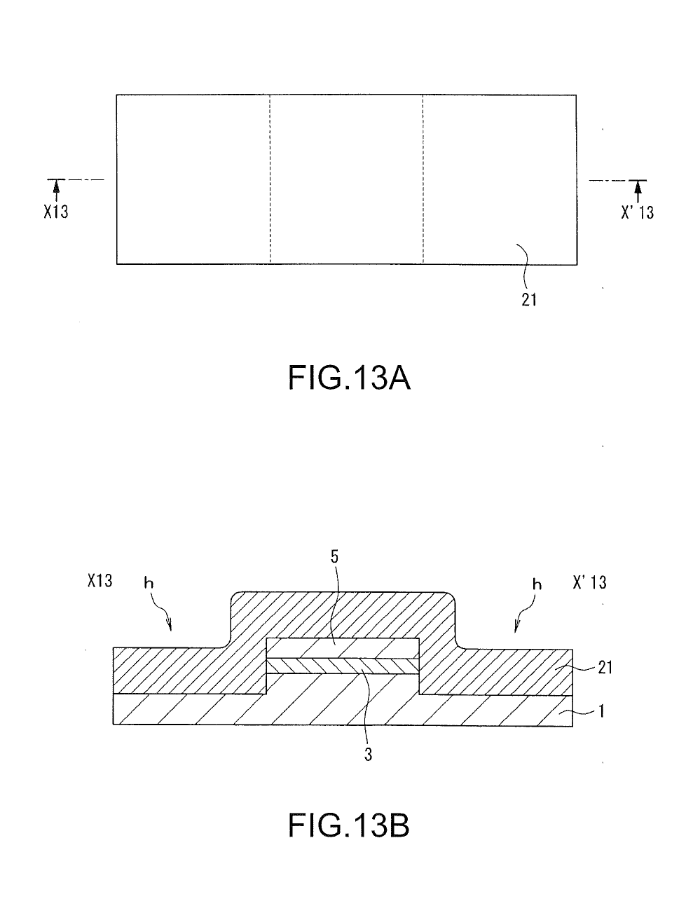

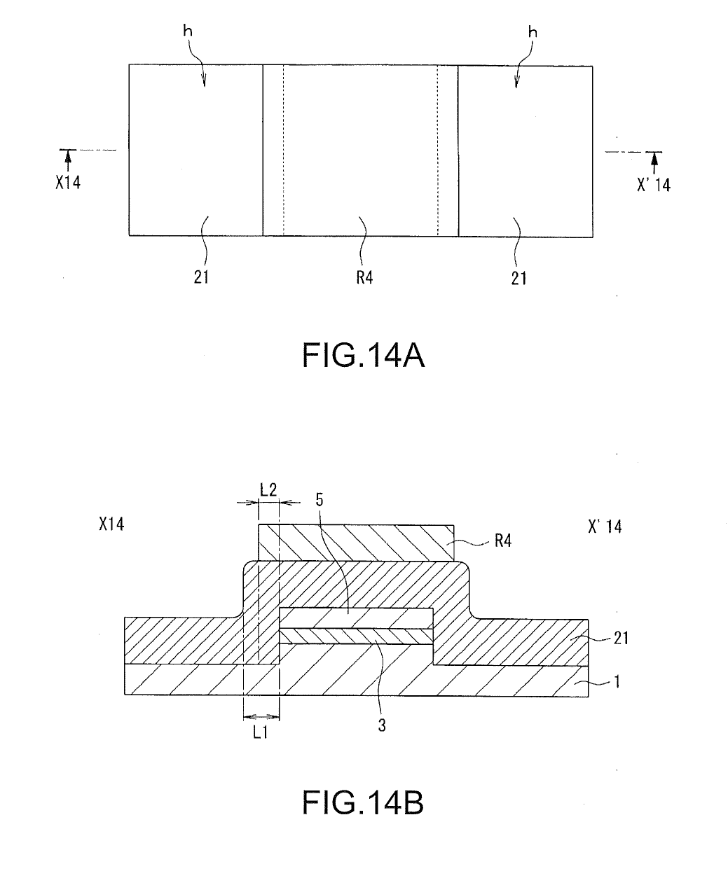

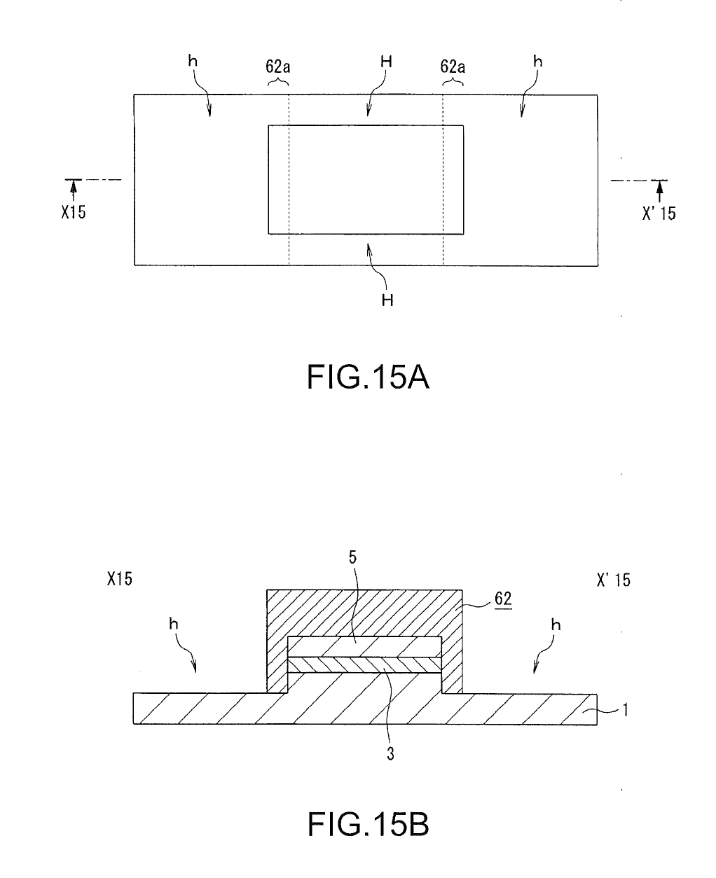

Next, as shown in FIGS. 13A and 13B, the support film 21 is formed on the whole of the upper surface of the Si substrate 1. The support film 21 is, for example, a SiO₂ film, and formed by CVD. Next, as shown in FIGS. 14A and 14B, a resist pattern R4 is formed on the support film 21, and a part of the support film 21, a part of the Si layer 5, and a part of the SiGe layer 3 are sequentially etched by using the resist pattern R4 as a mask. As a result, as shown in FIGS. 15A and 15B, a support 62 is formed from the support film 21 while the groove H is formed so as to have the Si substrate 1 as the bottom thereof and expose the sides of the Si layer 5 and the SiGe layer 3.

Here, in the third embodiment, as shown in FIGS. 14A and 14B, when the support 62 is formed, a portion to be sidewalls of the support 62 is etched in whole so as to be a thin film. The sidewalls are made thin obviously to an extent in which ability of the support 62 to support the Si layer 5 is not affected. For example, when a film thickness of the sidewalls of the support 62 before being thinned is L1, and a film thickness thereof after being thinned is L2, L1 should be about 400 nm, while L2 should be about 200 nm. That is, L2 is about a half of L1.

Further, as shown in FIGS. 15A and 15B, after the support 62 having sidewalls 62a having been thinned is formed, an SOI structure is formed with the same procedure as that of the first embodiment. That is, an etchant such as a hydrofluoric-nitric acid solution is brought into contact with the respective sides of the SOI layer 5 and the SiGe layer 3 through the groove H (e.g. refer to FIG. 4A) so as to selectively etch and remove the SiGe layer 3, forming the cavity 25 (e.g. refer to FIG. 5B). Then, the Si substrate 1 is placed in an oxidizing atmosphere of oxygen (O₂) or the like so as to thermally oxidize the upper surface of the Si substrate 1 and the lower surface of the Si layer 5 that are facing inside of the cavity 25, thereby forming the BOX layer 31 in the cavity 25 (e.g. refer to FIG. 6B).

At this time, the sidewalls 62a of the support 62 are weakened to the extent in which the support ability for the Si layer 5 is not affected by being thinned. Therefore, by receiving a softening effect of the support 62 itself due to a high temperature and a stress caused by the volume expansion of the BOX layer 31, the sidewalls 62a can be stretched in the upper direction and the Si layer 5 can be lifted.

As the above, according to the method for manufacturing a semiconductor device of the third embodiment, the Si layer 5 is lifted up in accordance with the volume expansion of the BOX layer 31 similarly to the first embodiment, thereby releasing force to push upward applied to the SOI layer 5 from the BOX layer 31. Therefore, the same advantageous effect as the first embodiment can be obtained.

In the first through third embodiments described above, the Si substrate 1 corresponds to a “semiconductor substrate”, the SiGe layer 3 corresponds to a “first semiconductor layer”, and the Si layer 5 corresponds to a “second semiconductor layer” of the invention. Further, the support recess h corresponds to a “first groove” and the grove H corresponds to “second groove” of the invention. Furthermore, the SiO₂ film (BOX layer 31) corresponds to a “buried oxide film”, while the Si film 51 corresponds to an “expansion member” of the invention.

What is claimed is:

1. A method for manufacturing a semiconductor device, comprising:
forming a first semiconductor layer and a second semiconductor layer sequentially on a semiconductor substrate;
forming a first groove penetrating the first semiconductor layer and the second semiconductor layer by partially etching the first semiconductor layer and the second semiconductor layer;
forming a support covering the second semiconductor layer from inside of the first groove to a surface of the second semiconductor layer so as to support the second semiconductor layer;
etching a sidewall formed in the first groove of the support so as to render the sidewall thin;
forming a second groove exposing the first semiconductor layer by sequentially etching a part of the second semiconductor layer and a part of the first semiconductor layer;
forming a cavity between the semiconductor substrate and the second semiconductor layer by etching the first semiconductor layer through the second groove under an etching condition in which the first semiconductor layer is more easily etched than the second semiconductor layer; and
forming a buried oxide film by thermally oxidizing an upper surface of the semiconductor substrate and a lower surface of the second semiconductor layer that are facing inside of the cavity.

2. The method for manufacturing a semiconductor device according to claim 1, wherein the etching the sidewall to render the sidewall thin includes forming a slit by partially etching the sidewall.

3. The method for manufacturing a semiconductor device according to claim 1 further comprising forming side surfaces of the second semiconductor and the first semiconductor that face the first groove of the second semiconductor layer and the first semiconductor layer to be in a continuous tapered shape in a sectional view so as to spread gradually wider from the second semiconductor layer to the first semiconductor layer before the support is formed.

4. The method for manufacturing a semiconductor device according to claim 2 further comprising filling the slit with an expansion member whose volume expands by thermal oxidation before the buried oxide film is formed.
